(19) United States
(12) Patent Application Publication
(10) Pub. No.: US 2020/0071956 A1
(43) Pub. Date: Mar. 5, 2020

(54) Security Indication Device and Combination Lock

(71) Applicant: The United States of America as represented by the Secretary of the Navy, San Diego, CA (US)

(72) Inventors: Stephen D. Russell, San Diego, CA (US); Joanna N. Ptasinski, San Diego, CA (US)

(21) Appl. No.: 16/115,822

(22) Filed: Aug. 29, 2018

(51) Int. Cl. E05B 39/00; E05B 17/10; E05B 37/00; H02N 2/18

(52) U.S. Cl. CPC E05B 39/00; E05B 17/10; H01L 41/20; E05B 37/00; H02N 2/186; E05B 39/007

(57) ABSTRACT

An electronic combination lock comprising a rotatable dial, an energy-harvesting device operatively connected to and configured to harvest energy from the rotatable dial, an energy-storage device operatively connected to and configured to be powered by the energy-harvesting device, a security status indicator operatively connected to and configured to by powered by the energy storage device, and logic configured to determine whether the combination lock is in a secure state and to activate the security-status indicator when the electronic combination lock is not in a secure state. A security-indication device for use with a combination device. A method for indicating a combination lock is not in a secure state comprising the steps of harvesting energy, storing the harvested energy, determining whether the combination lock is in a secure state, and, upon determining the combination lock is not in a secure state, activating a security-status indicator by powering it with stored energy.

### FEDERALLY SPONSORED RESEARCH AND DEVELOPMENT

The Security Indication Device and Combination Lock is assigned to the United States Government and is available for licensing and commercial purposes. Licensing and technical inquiries may be directed to the Office of Research and Technical Applications, Space and Naval Warfare Systems Center Pacific (Code 72120), 53560 Hull Street, San Diego, Calif., 92152, via telephone at (619) 553-2778, or email at ssc_pac_t2@navy.mil. Reference Navy Case 103776 in all communications.

### BACKGROUND OF THE INVENTION

### 1. Field of the Invention

The present invention relates generally to locks, and more particularly to combination locks.

### 2. Description of the Related Art

Rotary-dialed combination locks are often used to secure safes, filing cabinets, gym lockers, luggage containers, rooms, and other spaces. This specification refers to all such securable areas as spaces. In order to open a lock, a user enters a predetermined sequence of numbers by rotating the lock's dial in a predetermined sequence. While some variations exist, the process for securing a container generally involves the steps, in sequence, of: (1) closing the container; (2) engaging the lock's security mechanism (often a deadbolt); and (3) spinning the lock's dial in one direction a number of times (typically three full revolutions). The last step “scrambles” the combination lock, resetting it to a fully secure state. In some implementations, spinning the dial at step (3) above automatically performs step (2).

Combination locks are often subject to a security vulnerability. If a user does not spin the dial sufficiently to adequately scramble the combination, then the lock may not be entirely reset. In this case, the lock may act as if at least a portion of the proper combination was entered. In this state, the lock is easier to open than it should be, and the container is less than fully secure, increasing the likelihood that the contents of the container may be compromised.

Prior attempts at addressing this concern involved training for users of secure containers. Users may also have been required to log when the lock is unlocked and the container is opened, where the process of logging is intended to remind the users of the proper security procedures. Warning notices may also be posted, and inspectors may be sent around to audit security procedures. In some circumstances, security may be enhanced by requiring multiple-person integrity to open or secure a container, with each one monitoring the other's adherence to proper security procedures.

However, with user-centric remedies, security problems still arise, resulting from user fatigue, carelessness, or simple inattention to what is often a routine task. Compounding the problem is the fact that existing locks give no indication that they have been adequately secured or scrambled, resulting in containers visually appearing to be securely locked when it may not be.

### SUMMARY OF THE INVENTION

The present invention is an electronic combination lock comprising a rotatable dial, an energy-harvesting device operatively connected to and configured to harvest energy from the rotatable dial, an energy-storage device operatively connected to and configured to be powered by the energy-harvesting device, a security status indicator operatively connected to and configured to by powered by the energy storage device, and logic configured to determine whether the combination lock is in a secure state and to activate the security-status indicator when the electronic combination lock is not in a secure state.

Alternatively, the invention may be a security-indication device for use with a combination device comprising an energy-harvesting device configured to be operatively connected to and configured to harvest energy from a rotatable dial of the combination lock, an energy-storage device operatively connected to and configured to be powered by the energy harvesting device, a security-status indicator operatively connected to and configured to be powered by the energy-storage device, and logic configured to determine whether the combination lock is in a secure state and to active the security-status indicator when the combination lock is not in a secure state.

In accordance with one aspect of the invention, a method for indicating that a combination lock is not in a secure state comprising the steps of harvesting energy, storing the harvested energy, determining whether the combination lock is in a secure state, and, upon determining the combination lock is not in a secure state, activating a security-status indicator by powering it with stored energy.

### BRIEF DESCRIPTION OF THE DRAWINGS

Throughout the several views, like elements are references using like elements. The elements in the figures are not drawn to scale, and some dimensions may be exaggerated for clarity.

FIG. 1A is a front perspective view of an electronic combination lock.

FIG. 1B is a rear perspective view of an electronic combination lock.

FIG. 2 is a flowchart of a representative method for telling a user when a lock is not secure.

FIG. 3 is a generalized schematic of a security-indication device.

FIG. 4 is a table showing some magnetostrictive materials usable in kinetic-energy harvesting.

### DETAILED DESCRIPTION OF THE INVENTION

While this invention may be embodied in different forms, the drawings and this section describe in detail specific embodiments of the invention with the understanding that the present disclosure is to be considered merely a preferred embodiment of the invention, and is not intended to limit the invention in any way.

The present invention teaches presenting the user an indication which is hard to ignore that the lock is not secure. For example, a light may be set to start flashing when the lock enters a non-secure state (e.g., when the user opens the lock to access the container). The light continues to flash until the container is closed and the lock is properly secured. If a user does not adequately secure the lock, the flashing light reminds the user that the task of securing the container is not yet complete.

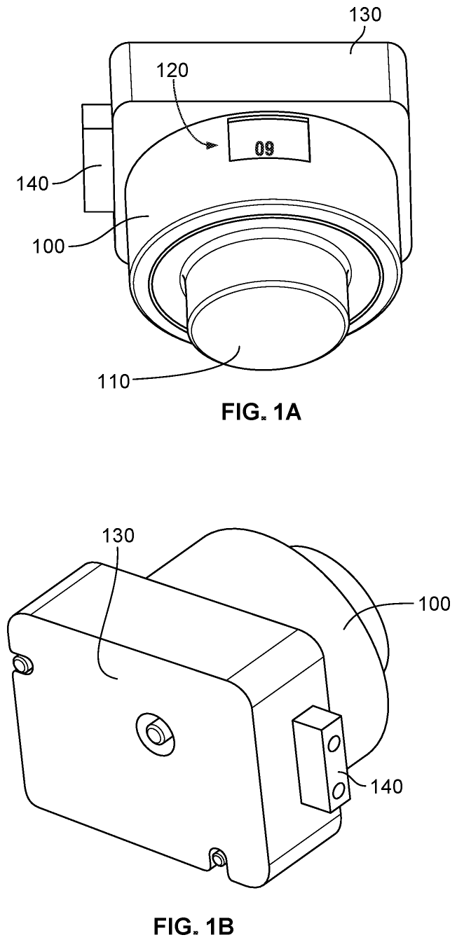

FIG. 1A shows an exemplary electronic lock 100 in detail. This electronic lock 100 has a display screen 120 showing the user the number to which the lock's dial 110 has been turned. As is well known, a user opens the lock 100 by rotating the dial 110 in a specific direction until the first number of the lock's combination is shown in the display screen 120. Then, the dial 110 is rotated in the other direction until the next number in the combination is displayed. This continues until the proper sequence of the lock's entire combination has been displayed, and the lock 100 opens.

FIG. 1B shows the back of the lock 100. When the proper combination is entered into the lock, its internal mechanism (not shown) contained in the housing 130 retracts the deadbolt 140, allowing the door of the container (not shown) to be opened.

It should be noted that several different embodiments are envisioned. In a first set of embodiments, the presently claimed techniques are built into the body of a lock such as the lock 100 shown in FIG. 1A and FIG. 1B. In other embodiments, the present claimed techniques and devices may be added to an existing lock 100. The details of the specification may be applicable to both sets of embodiment (as well as others), while the particulars of specific embodiments may be emphasized when appropriate.

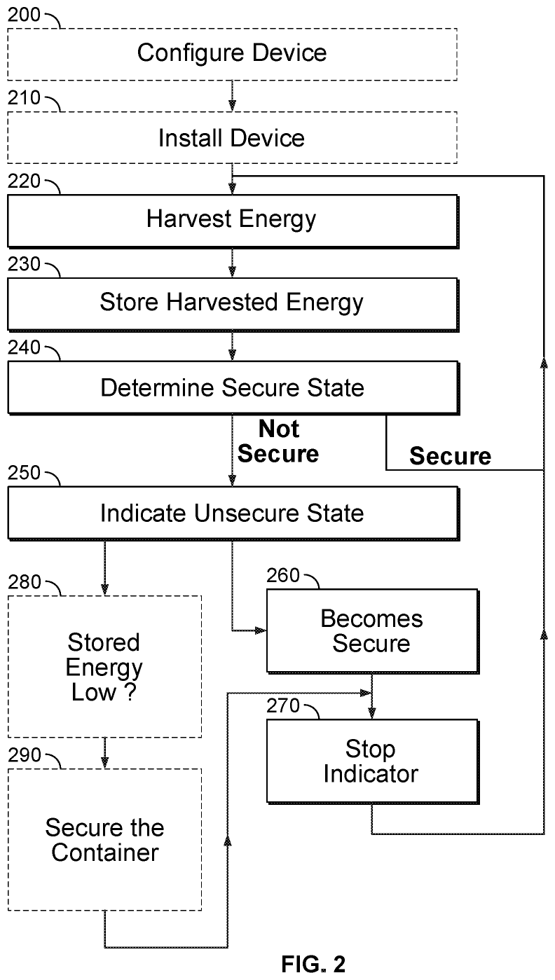

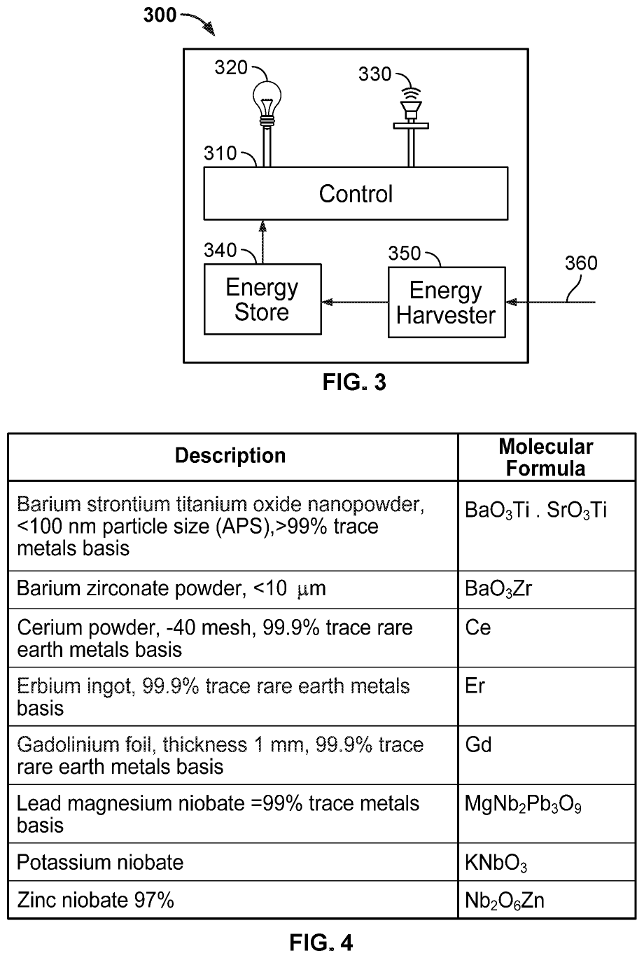

FIG. 2 is a flowchart showing a method for indicating the non-secure status of a lock 100 to a user. FIG. 3 is a schematic of the functional parts of a security indicator 300 that performs the method of FIG. 2. At step 200 of FIG. 2, the security indication device 300 is configured for future operation. When device 300 is built into the lock 100 by the lock's manufacturer, step 200 may be accomplished during the manufacturing process. For example, the operational logic built into the lock 100 “knows” whether its deadbolt 140 is in an extended or a retracted state. The logic of the lock 100 also directly monitors the motion of the dial 110 and “knows” whether or not the dial 110 has been turned sufficiently to “scramble” the lock 100. The logic of the lock 100 can simply tell the control logic 310 of the security indicator 300 this information, and the security indicator 300 acts appropriately. In some embodiments, the control logic 310 is a part of the operational logic of the lock 100.

For add-on devices, step 200 may involve “teaching” the security indicator 300 how to know when the lock 100 (to which the add-on device is attached) is secure. In one example, the security indicator 300 can be configured to accept that this particular lock 100 100 is secure when its dial 110 has been detected turning in one direction for at least three full revolutions. Other configuration settings are possible and depend upon the nature of the lock 100. In some embodiments, this step 200 is optional because a default configuration works for many types of lock 100.

The integrated security indicator 300 may leave the factory already install in the lock 100. In other embodiments, the security indicator 300 is installed at step 210. This involves at least physically attaching the security indicator 300 to the lock 100 (or to the container that the lock 100 secures). In certain embodiments, the installation may involve other considerations. The security indicator 300 needs energy to operate (see especially steps 240, 250, and 290 discussed below). Without such energy, the security of the container may be compromised. Batteries can provide the needed energy, but they may become depleted if not regularly checked and change. So instead of or in addition to batteries, the security indicator 300 will at step 220 harvest energy 360 from its environment in order to operate.

There are many known ways to harvest such energy 360. In one example, when the dial 110 of the lock 100 is spun, the kinetic energy of the spinning dial 110 can drive a small transduction mechanism on the dial's shaft which converts the kinetic energy to electrical energy, which can be used to power the security indicator 300. In other example, some safes (and other security containers) can include a handle which a user turns to open the safe. A transducer installed in the handle can directly harvest kinetic energy from the handle's turning. Additionally, energy can be indirectly harvested from the vibrations set up in the security container when the handle is turned.

Known transduction mechanisms generally fall into the microelectromechanical, piezoelectric, electromagnetic, and electrostatic categories. The electromagnetic transducers couple a static magnetic field with a moving solenoid (e.g., placed on a rotating shaft of the lock's dial 110). Electrostatic transducers include a variable capacitor with one electrode attached to an oscillating mass. The mass may be set to oscillating by vibrations in the secure container set up when the user spins the lock's dial 110 or turns the handle, for example. The kinetic energy of the oscillating mass is then converted to electrical energy.

Other known harvesting mechanisms, such as the harvester 350, pull thermal or mechanical energy from the environment using magnetostrictive, piezoelectric, or other materials. For example, a heavy steel safe has a large thermal mass. If the safe cools down overnight, then in the morning, there may be a significant temperature difference between the safe and the surrounding air. This temperature difference can be enough to drive a thermal energy harvester 350. A list of some of the magnetostrictive materials which may be useful for energy harvesting is provided in FIG. 4.

In some embodiments, the security indicator 300 draws energy 360 from more than one type of energy harvester 350. This both boosts the amount of energy that can be harvested and increases the odds that at least one harvester 350 will be providing enough energy in the particular environment that the security indicator 300 is in.

Even when other sources of harvested energy are available, there are several advantages to harvesting energy directly form the rotating dial 110. The spinning dial 110 is a source of substantial energy provided exactly when the security indicator 300 needs it. Where the security indicator 300 is built into the lock 100, a harvester 350 on the dial 110 makes for a clean, compact package. Thus, a security indicator 300 built into a lock 100 would probably harvest the kinetic energy of the spinning dial 110.

There are other advantages in those embodiments where the security indicator 300 is added on to an existing lock 100. Because spinning the dial 110 is central to the operation of the combination lock 100, if the security indicator 300 knows directly how the dial 110 is spinning, then it can also know the status of the lock 100 (see the discussion of steps 240 and 260 below). However, due to circumstances peculiar to each installation, a security indicator 300 added to an existing lock 100 may or may not be able to harvest that spinning kinetic energy. In cases where this is not possible, use of some of the other energy-harvesting mechanisms is indicated.

No matter how the energy 360 is harvested at step 220, it is stored for use at step 230. In some embodiments, the harvested energy store 340 in one of or a combination of a rechargeable battery, a trickle-charged capacitor or supercapacitor, or even some physical energy storage devices such as a pendulum or rotating mass.

It is worth noting that steps 220 (harvesting energy) and 230 (storing harvested energy) are going on at all times regardless of the status of the security indicator 300 with respect to the rest of the method depicted in FIG. 2.

The harvested energy is used to power the security indicator 300. In step 240, a control circuit 310 in the security indicator 300 determines whether the lock 100 is in a secure state. When the security indicator 300 is built into an electronic combination lock 100, that determination can be made by the operational logic within the lock 110.

When the security indicator 300 is added on to an existing lock 100, then the determination can be based on analyzing the recent history of the lock 100 and possibly the history of the container to which the lock 100 is attached. For example, if the energy harvester 350 is connected to and driven by the lock's dial 110, then it can be determined that the dial 110 is being spun and that the lock 100 may be entering a non-secure state.

In other situations, vibrations that power a kinetic-energy harvester 350 of step 220 can be analyzed to determine the security status of the lock 100. The art of this kind of activity analysis has been advanced recently. As one example from the art, the analysis of vibrations of a mobile phone can be used to tell if the phone's owner is walking, driving, or riding a train. When the same type of vibration analysis is applied in the present situation, the control logic 310 of the security indicator 300 can determine that the dial 100 is being spun in one direction or the other, how far or whether the handle of a security container has been turned, whether the deadbolt 140 of the lock 100 has moved, and whether the door of a security container has been opened or closed.

In yet another embodiment, a change in the amount of energy stored 340 at step 230 can indicate that something is happening to the lock 100 which may be bringing it to a non-secure state. Other possibilities are readily imaged. In any case, the control circuit 310 of the security indicator 300 differentiates between a user simply spinning the dial 110 and actually opening the security container.

However, it has been determined, if the lock 100 is seen to be still in a secure state, then the method returns to steps 220 (harvesting energy) and 230 (storing the harvested energy), and the security indicator 300 awaits further developments. However, if the lock 100 is determined to be in a non-secure state, then the security indicator 300 brings that information to the user's attention in step 250. In some embodiments, the security indicator 300 waits a reasonable amount of time after the container enters a non-secure state before alerting the user.

There are several possible mechanisms for alerting the user. The security indicator 300 can turn on an indicator 320, possibly flashing, to attract the user's attention. A non-continuous audible indication can be given through an indicator 330, which may be, in one embodiment, a speaker.

Similarly, a tactile warning can be given by driving a vibration motor (such as those found in mobile phones). This option works in two ways: (1) when driven by energy from the energy store 340, the vibration motor creates a tactile warning; or (2) when passively moved by vibrations in the lock 100 or in the security container, it can harvest its own kinetic energy 360 and help to charge up the energy store 340.

If more than one indicator is used, these indicators can be used in series. For example, the indicator 320 is turned on as soon as a non-secure state is detected, but the indicator 330 is only turned on after a significant period of time has passed. If more than one indicator is used at the same time, they can be pulsed intentionally out of phase to further draw the user's attention.

As the amount of power available to the security indicator 300 will generally be fairly low, the indicators should draw as little power as feasible while still being able to attract the user's attention. For example, the indicator 320 may be any type of light-emitting diode which emits in the visible spectrum. The indicator 330 can be very small, such as a microelectromechanical device.

In general, because the indicators 320 and 330 are non-static, they will be harder for a user to ignore than a static posted sign.

The security indicator's control logic 310 continues to monitor the status of the lock 100. If it determines that the lock has entered a secure state (step 260), then it turns off the indicators 320 and 330 at step 270 and awaits further developments while harvesting energy at step 220 and storing energy at step 230.

For a security indicator 300 built into the lock 100, the determination of step 260 comes directly from the operational logic within the lock 100. That is, the lock 100 tells the security indicator 300 that the lock 100 is secure. A security indicator 300 added on to an existing lock 100 can use the same type of methods discussed above in relation to step 240 to determine that the lock 100 has now entered a secure state. For example, either direct monitoring of the lock's dial 110 or analysis of received vibrations may indicate that the dial 110 has been spun the requisite number of times to adequately scramble it.

Some embodiments of the security indicator 300 include the logic of steps 280 and 290. The energy store 340 is of limited capacity, and it would be unwise for the security indicator 300 to use up all of its stored energy before the lock 100 was brought back to a secure state. Were that to happen, the lock 100 would be non-secure, possibly without the user's being warned about it. To avoid this scenario, if the amount of stored energy gets too low at step 280, then the security indicator 300 tells the lock 100 to secure itself at step 290. When the security indicator 300 is built into the lock 100, it can throw the deadbolt 140.

From the above description of the present invention, it is manifest that various techniques may be used for implementing its concepts without departing from the scope of the claims. The described embodiments are to be considered in all respects as illustrative and not restrictive. The method disclosed herein may be practiced in the absence of any element that is not specifically claimed and/or disclosed herein. It should also be understood that the present invention is not limited to the particular embodiments described herein, but is capable of being practiced in many embodiments without departure from the scope of the claims.

1. An electronic combination lock comprising:
a rotatable dial;
an energy-harvesting device operatively connected to and configured to harvest energy from the rotatable dial;
an energy-storage device operatively connected to and configured to be powered by the energy-harvesting device;
a security-status indicator operatively connected to and configured to be powered by the energy-storage device; and
logic configured to determine whether the combination lock is in a secure state and to activate the security-status indicator when the electronic combination lock is not in a secure state;
wherein the logic is configured to determine whether the combination lock is in a secure state based, at least in part, on an element selected from the group consisting of: an amount of energy harvested by the energy-harvesting device, an amount of energy stored in the energy-storage device, a change in the amount of energy stored in the energy-storage device, an amount of rotation of the rotatable dial, and a direction of rotation of the rotatable dial.

2. The electronic combination lock of claim 1 wherein the energy-storage device comprises an element selected from the group consisting of: a capacitor, a supercapacitor, a battery, and a physical-energy storage device.

3. The electronic combination lock of claim 1 wherein the security-status indicator is configured to produce an element selected from the group consisting of: a light, a time-varying light, a sound, a time-varying sound, and a vibration.

4. The electronic combination lock of claim 1 wherein the logic is further configured to bring the electronic combination lock to the secure state when an amount of energy stored in the energy-storage device is below a threshold.

5. The electronic combination lock of claim 1 comprising a visual security-status indicator and an audible security-status indicator, wherein the logic is configured to activate the visual security-status indicator when the electronic combination lock leaves the secure state and to activate the audible security-status indicator upon a set time delay after the electronic combination lock leaves the secure state.

6. The electronic combination lock of claim 1 wherein the logic is further configured to deactivate the security-status indicator when the electronic combination lock is in the secure state.

7. The electronic combination lock of claim 1 further comprising:
at least a second energy-harvesting device operatively connected to and configured to power the energy-storage device.

8. A security-indication device for use with a combination lock, the security-indication device comprising:
an energy-harvesting device configured to be operatively connected to and configured to harvest energy from a rotatable dial of the combination lock;
an energy-storage device operatively connected to and configured to be powered by the energy-harvesting device;
a security-status indicator operatively connected to and configured to be powered by the energy-storage device; and
logic configured to determine whether the combination lock is in a secure state and to activate the security-status indicator when the combination lock is not in a secure state;
wherein the logic is configured to determine whether the combination lock is in a secure state based, at least in part, on an element selected from the group consisting of: an amount of energy harvested by the energy-harvesting device, an amount of energy stored in the energy-storage device, a change in the amount of energy stored in the energy-storage device, an amount of rotation of the rotatable dial, and a direction of rotation of the rotatable dial.

9. The security-indication device of claim 8 wherein the energy-harvesting device comprises an electric generator configured to harvest energy from rotation of the rotatable dial.

10. The security-status indication device of claim 8 wherein the energy-storage device comprises an element selected from the group consisting of: a capacitor, a supercapacitor, a battery, and a physical-energy storage device.

11. The security-status indication device of claim 8 wherein the security-status indicator is configured to produce an element selected from the group consisting of: a light, a time-varying light, a sound, a time-varying sound, and a vibration.

12. The security-status indication device of claim 8 comprising a visual security-status indicator and an audible security-status indicator, wherein the logic is configured to activate the visual security-status indicator when the combination lock leaves the secure state and to activate the audible security-status indicator upon a set time delay after the combination lock leaves the secure state.

13. The security-status indication device of claim 8 wherein the logic is further configured to deactivate the security-status indicator when the combination lock is in the secure state.

14. (canceled)

15. The security-status indication device of claim 8 further comprising:
at least a second energy-harvesting device operatively connected to and configured to power the energy-storage device.

16. A method for indicating that a combination lock is not in a secure state, the method comprising:
harvesting energy;
storing harvested energy;
determining whether the combination lock is in a secure state; and
when the combination lock is not in a secure state, activating a security-status indicator by powering it with stored energy;
wherein determining whether the combination lock is in a secure state is based, at least in part, on an element selected from the group consisting of: an amount of energy harvested, an amount of energy stored, a change in the amount of energy stored, an amount of rotation of a rotatable dial of the combination lock, and a direction of rotation of the rotatable dial of the combination lock.

17. The method of claim 16 comprising activating a visual security-status indicator when the combination lock leaves the secure state and activating an audible security-status indicator upon a set time delay after the combination lock leaves the secure state.

18. The method of claim 16 further comprising:
deactivating the security-status indicator when the combination lock is in the secure state.

19. The method of claim 16 further comprising:
bringing the combination lock to the secure state when an amount of stored energy is below a threshold.

20. (canceled)

21. The electronic combination lock of claim 1, wherein the security-status indicator is configured to provide a tactile warning.
